(19) United States
(12) Patent Application Publication
(10) Pub. No.: US 2024/0405018 A1
(43) Pub. Date: Dec. 5, 2024

(54) FIELD-PLATED RESISTOR

(71) Applicant: TEXAS INSTRUMENTS INCORPORATED, Dallas, TX (US)

(72) Inventors: Zachary K Lee, Fremont, CA (US); Wenyuan SUN, Allen, TX (US)

(21) Appl. No.: 18/326,389

(22) Filed: May 31, 2023

(51) Int. Cl. H01L 27/06; H01L 27/088; H01L 29/40; H01L 29/66; H01L 29/78; H01L 29/8605

(52) U.S. Cl. CPC H01L 27/0629; H01L 27/088; H01L 29/405; H01L 29/6675; H01L 29/7803; H01L 29/8605

(57) ABSTRACT

A semiconductor device includes a semiconductor substrate. A well resistor is in the semiconductor substrate. A field plate is above the well resistor. An insulator is between the well resistor and the field plate. The well resistor includes a first terminal and a second terminal. The field plate may be coupled to the first terminal or the second terminal.

### BACKGROUND

A well resistor is a type of resistor that is formed in the substrate of an integrated circuit. The well resistor is formed by doping the substrate with a semiconductor material to form a region of increased dopant concentration. Well resistors can be used in analog circuits, such as amplifiers and filters, and in digital circuits, such as logic gates and registers. For example, a well resistor can be used as a pull-up resistor in a logic gate, or as a load resistor or bias resistor in an amplifier. Well resistors are popular because they can be implemented without additional masks or process steps.

### SUMMARY

In one example, a semiconductor device includes a semiconductor substrate. A well resistor is in the semiconductor substrate. A field plate is above the well resistor. An insulator is between the well resistor and the field plate.

In another example, an integrated circuit includes a resistor well extending into a semiconductor substrate. A dielectric layer extends into the resistor well. A conductive field plate is located over the dielectric layer. The conductive field plate is configured to modulate a majority carrier distribution within the resistor well while the resistor well conducts a current.

In a further example, a method includes forming an insulation layer on a semiconductor substrate, and doping a resistor well extending into the semiconductor substrate. The method also includes depositing a layer of a conductive material spaced apart from the semiconductor substrate by the insulation layer, and etching the conductive material to form a field plate over the resistor well.

### BRIEF DESCRIPTION OF THE DRAWINGS

FIG. 1A is a side cross-section view of an example field-plated well resistor.

FIG. 1B is a side cross-section view of another example field-plated well resistor.

FIG. 2 is a top view of an example field-plated well resistor, e.g., the field-plated well resistor of FIG. 1A.

FIG. 3 illustrates majority carrier (hole) concentration in example well resistors as a function depth into the resistor substrate.

FIG. 4 illustrates I-V curves of the example well resistors of FIG. 3.

FIG. 5 is a flow diagram of an example method for fabricating a field-plated well resistor.

FIGS. 6A-6M are cross-section views showing examples of the various fabrication stages of the method of FIG. 5.

FIG. 7 is a side cross-section view of an example integrated circuit that includes a field-plated resistor coupled to a transistor.

FIG. 8 is a block diagram of an example driver circuit that includes a field-plated well resistor.

### DETAILED DESCRIPTION

Various disclosed methods and devices of the present disclosure may be beneficially applied to a resistor having a reduced or adjustable voltage coefficient of resistance. While such embodiments may be expected to provide improved circuit performance in some implementations, no particular result is a requirement unless explicitly recited in a particular claim.

A resistor may, in general, have a non-zero voltage coefficient of resistance, often referred to herein simply as a voltage coefficient. The voltage coefficient of a resistor is a measurement of how much the resistance of the resistor changes with applied voltage. For example, a resistor with a voltage coefficient of 100 parts-per-million per volt (100 ppm/V) will have a 0.01% change in resistance for every 1 V change in applied voltage. A low voltage coefficient is desirable in some applications. For example, a low voltage coefficient may be desirable for a resistor used in a current limiting application to reduce the variation in power dissipated by the resistor. A high voltage coefficient may be desirable in other applications.

In the resistors described herein, the voltage coefficient can be decreased or increased. The resistors include a well resistor with a field plate provided above the well resistor. An insulating layer is provided between the well resistor and the field plate. The field plate may be conductively coupled to one of the two terminals of the well resistor. Connection of the field plate to a lower-voltage (current sink) terminal of a p-type well resistor causes carriers to accumulate under the field plate, thereby reducing the voltage coefficient or the resistor. Connection of the field plate to a higher-voltage (current source) terminal of the p-type well resistor causes depletion of carriers under the field plate, thereby increasing the voltage coefficient of the resistor. The effect on the voltage coefficient is reversed for n-type well resistors. In some other examples the field plate is connected to a controllable voltage source, providing modulation of the voltage coefficient independent of the current flow through the resistor.

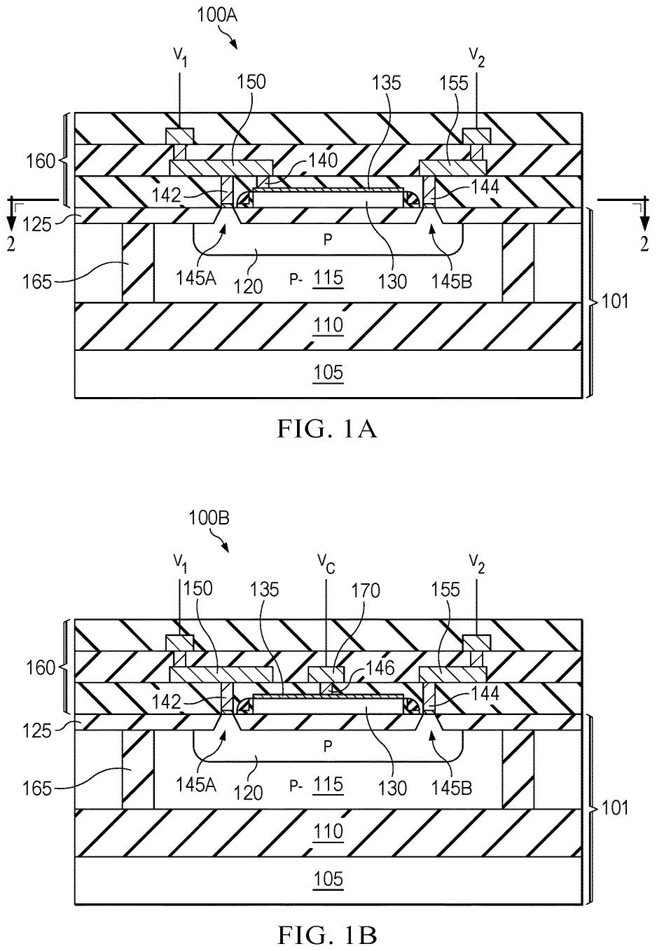

FIG. 1A is a side cross-section view of an example electronic device, a field-plated well resistor 100A, over and extending into a semiconductor substrate 101. The semiconductor substrate 101 includes a handle layer 105, a buried oxide (BOX) layer 110 and an epitaxial layer 115. The handle layer 105 may be bulk silicon or other semiconductor material. The BOX layer 110, which may be omitted in some examples, may be a portion of a silicon-on-insulator (SOI) substrate. While the epitaxial layer 115 in the illustrated example is lightly doped p-type silicon (active silicon), the handle layer 105 and epitaxial layer 115 may be any other combinations of n-type or p-type material.

The well resistor 100A further includes p-type resistor well 120 that extends into the epitaxial layer 115. The resistor well 120 may be formed by doping the epitaxial layer 115 with a p-type dopant. An insulation layer 125 (e.g., an oxide layer) isolates the resistor well 120 from a field plate 130. The field plate 130 is formed of a conductive material, e.g., polysilicon in the illustrated example. The illustrated example also includes a silicide layer 135 on the field plate 130 to provide high conductivity. In some other examples a field plate may be provided by a metal structure in an interconnect layer (a metal interconnect layer).

A first vertical interconnect, or via, 140 conductively connects the field plate 130 to a first terminal 145A of the resistor well 120 via a second vertical interconnect 142 and a horizontal interconnect, or trace, 150 in a first metal layer (M1). A third vertical interconnect 144 is conductively connected to a second terminal 145B of the resistor well 120 and to a horizontal interconnect 155. For reference, the first terminal 145A may be referred to by a voltage V₁, and the second terminal 145B may be referred to by a voltage V₂. The resistor well 120 may be conductively coupled to other components formed in or over the semiconductor substrate 101 via other interconnections, such as for example unreferenced vertical interconnects and unreferenced horizontal interconnects a second metal layer (M2). The various interconnections are located within insulation layers 160 (e.g., one or more oxide or nitride layers). While two metal levels (horizontal interconnect levels) are shown, the field-plated well resistor 100A may include any number of metal levels. The illustrated interconnection configuration is for example only and not exclusive of other examples.

The insulation layer 125 in the illustrated example is a shallow trench isolation (STI) structure. In other examples the field-plated well resistor 100A may include any number of layers between the resistor well 120 and the field plate 130, for example a field oxide layer or a local oxidation of silicon (LOCOS) layer, one or more silicon oxide layers and/or one or more silicon nitride or silicon oxynitride layers. The spacing between the resistor well 120 and the field plate 130 (e.g., the thickness of the insulation layer 125) may be selected based on the voltage (e.g., a maximum operating voltage) across the resistor well 120, e.g., between the field plate 130 and the handle layer 105. For a higher voltage, the spacing between the resistor well 120 and the field plate 130 may be increased. For example, the field plate 130 may be formed in the M2 metal layer to provide a greater spacing between the resistor well 120 and the field plate 130. For a lower voltage, the spacing between the resistor well 120 and the field plate 130 may be decreased. For example, the field-plated well resistor 100A may be formed in a polysilicon layer or the M1 metal layer to provide a smaller spacing between the resistor well 120 and the field plate 130.

The field-plated well resistor 100A may also include an isolation trench structure 165 (e.g., a deep trench isolator) around the resistor well 120 and the field plate 130. The isolation trench structure 165 includes a trench in the semiconductor substrate 101 around the resistor well 120 and the field plate 130. The trench may be lined or filled with a dielectric material, such as silicon dioxide. In some examples, the dielectric material may be filled with a conductor such as polysilicon. If the substrate is an SOI substrate the isolation trench structure 165 may contact the BOX layer 110 as illustrated, thus conductively isolating the resistor well 120 from other devices that share the substrate 101. Similarly for examples that include a buried isolation layer, such as a buried n-type layer, the isolation trench may include n-type polysilicon thereby isolating the resistor well 120 by junction isolation.

Generally, the well resistor 100A may include any known or future-discovered configuration of resistor well and/or other implanted regions such as may be useful for, e.g., isolation of the resistor well. Thus, some other non-exclusive examples include a p-type resistor well within an n-type isolation well that is within a p-type epitaxial layer; a p-type resistor well within an n-type epitaxial layer; an n-type resistor well in a p-type epitaxial layer; an n-type resistor well within a p-type isolation well that is within an n-type epitaxial layer; an n-type resistor well within a p-type epitaxial layer; and an n-type resistor well within an n-type epitaxial layer. The illustrated BOX layer 110 and/or the isolation trench structure 165 may both be optionally omitted, the BOX layer 110 may be included and the isolation trench structure 165 excluded, or the isolation trench structure 165 included and the BOX layer 110 excluded. Furthermore, in some examples the epitaxial layer may be excluded such that the resistor well is formed within bulk semiconductor (e.g., silicon).

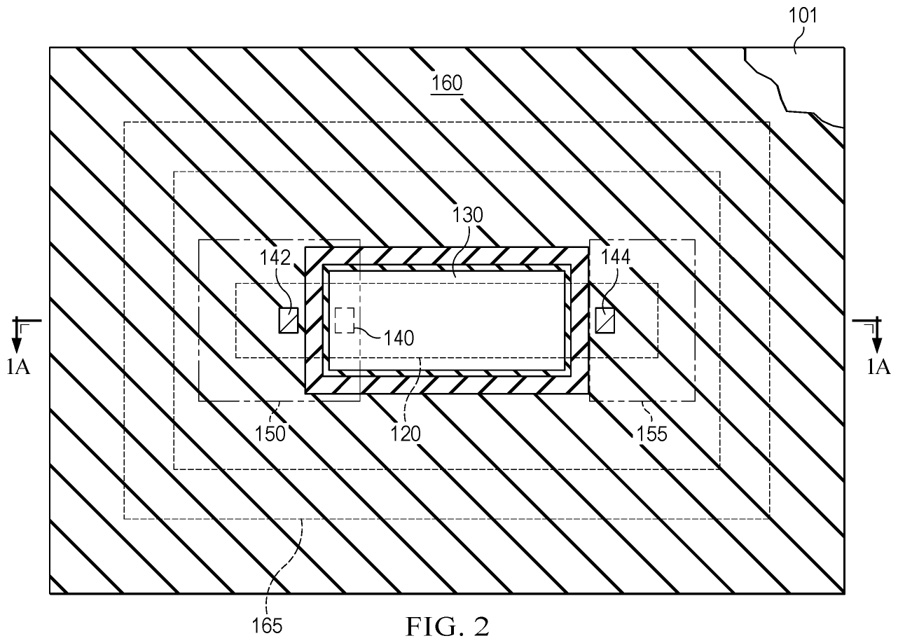

FIG. 2 is a top view of the field-plated well resistor 100 viewed as shown in FIG. 1A. In the illustrated example the resistor well 120 is in the form of a rectangular strip. The dimensions of the strip may be selected to implement a design resistance and conform to relevant design rules. In other examples the resistor well 120 may have another geometry, e.g., a serpentine path. The isolation trench structure 165 surrounds the resistor well 120 and the field plate 130.

FIG. 1B illustrates a field-plated well resistor 100B, in which the field plate 130 is conductively connected to a horizontal interconnect 170 by a vertical interconnect 146. The interconnect 170 provides a third terminal that may be referred to by a voltage V_{C}. The third terminal provides connection to the field plate 130 that may be biased independently of V₁ and V₂ when such independent control is desirable.

The field-plated well resistor 100A or field-plated well resistor 100B may be connected in an integrated circuit to implement a resistance between two circuit nodes. In one example the terminal 145A is connected to a circuit node that has a first voltage when operating, and the terminal 145B is connected to a circuit node that has a lower second voltage when operating. Thus, current flow in the resistor well 120 is from the terminal 145A to the terminal 145B in this example. In another example the terminal 145B has a higher voltage when operating, and the terminal 145A has a lower voltage, such that current flow in the resistor well 120 is from the terminal 145B to the terminal 145A. This aspect is addressed more fully below.

Recalling that the resistor well 120 may in general have a non-zero voltage coefficient, the field plate 130 provides the ability to at least partially reduce the magnitude of the voltage coefficient by modulating the carrier concentration within the resistor well 120. With continued reference to FIG. 1A, the resistivity of the resistor well 120 may be reduced by increasing the majority carrier concentration in a portion of the resistor well 120. Conversely, the resistivity may be increased by reducing the majority carrier concentration in a portion of the resistor well 120. Noting that when current flows from the terminal 145A to the terminal 145B, the terminal 145B will have a lower voltage than the terminal 145A due to IR voltage drop. The converse is true when current flows from the terminal 145B to the terminal 145A.

The inventor has discovered that this voltage difference may be exploited to selectively modify the voltage coefficient of the resistor well 120. In an example, when current flows from the terminal 145B to the terminal 145A, the terminal 145B will have a higher voltage than the terminal 145A. The higher voltage terminal may be referred to as the “high side terminal,” and the lower voltage terminal may be referred to as the “low side terminal.” If the resistor well 120 is p-type, the field plate 130 may be connected to the low side terminal, e.g., the terminal 145A. The lower voltage of the field plate 130 will attract holes to the region of the resistor well 120 nearest the field plate, creating a lower-resistance path that reduces the overall resistance of the resistor well 120. In another example with the same direction of current flow, the field plate 130 may be connected to the high side terminal, e.g., the terminal 145B. The higher voltage of the field plate 130 will repel holes from the region of the resistor well 120 nearest the field plate, creating a higher-resistance path that increases the overall resistance of the resistor well 120. If the resistor well 120 is n-type, the effects are reversed. In addition to the modulation of conductivity of the resistor well 120, the field plate 130 may also shield the resistor well 120 from noise and signals above the resistor well 120. Accordingly, the field plate 130 enables routing of high voltage signals above the field-plated well resistor 100A.

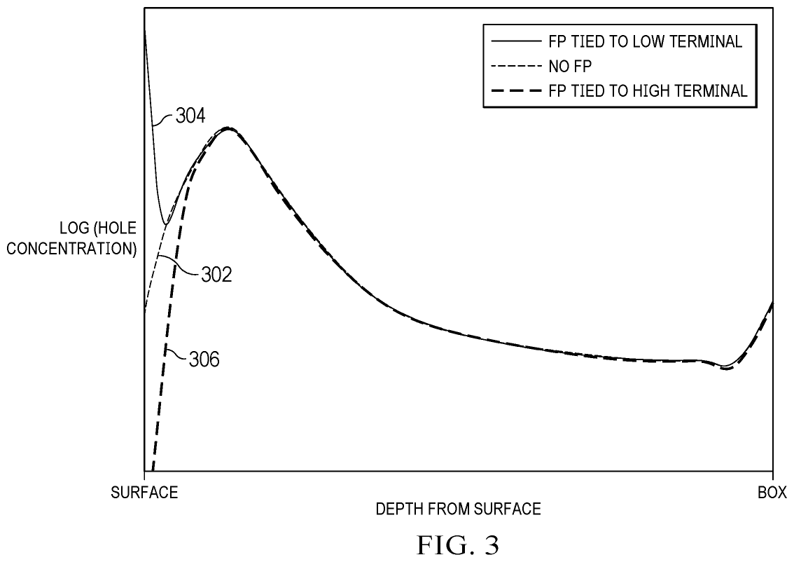

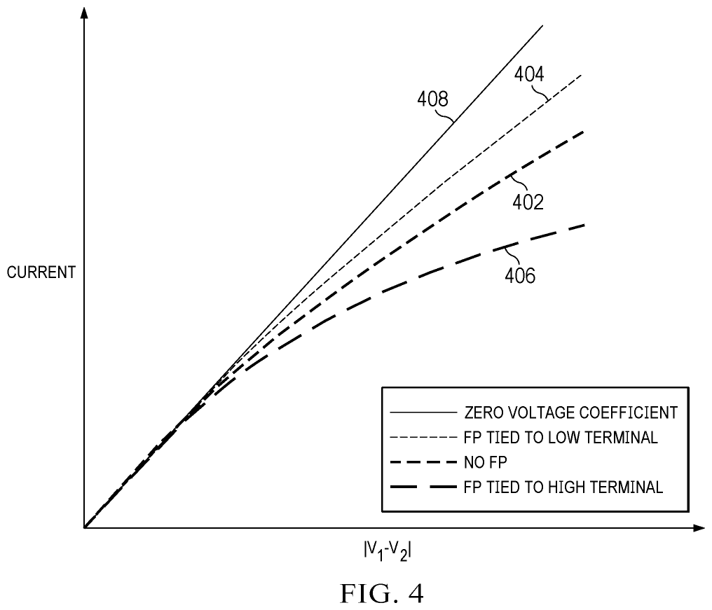

FIGS. 3 and 4 graphically illustrate aspects of the operation of the field-plated well resistor 100A for the example of current flow from the terminal 145B to the terminal 145A. FIG. 3 includes characteristics derived from modeling of three examples of hole concentration (log scale) versus depth between the insulation layer 125 and the buried oxide layer 110. Thus, these characteristics represent hole concentration within the p-type resistor well 120 with increasing depth below the insulation layer 125. A first characteristic 302 illustrates the hole concentration for a resistor similar to the model resistor 100A but omitting the field plate 130. The hole concentration is seen to increase rapidly from zero to maximum value, and then decrease smoothly with increased depth. A second characteristic 304 illustrates the hole concentration for a resistor constructed as shown in FIG. 1A, for which the terminal 145A is the low-side terminal for the direction of current flow. Thus, the field plate 130 is connected to the low-side terminal of the resistor well 120. In this case the hole concentration is observed to decrease from a maximum value near the insulation layer 125 to a local minimum, after which the concentration closely tracks the characteristic 302 of the resistor lacking the field plate. A third characteristic 306 illustrates the hole concentration for a resistor constructed otherwise as shown in FIG. 1A, but for which the field plate is connected to the high-side terminal 145B of the resistor well 120. (Note that this example is equivalent to current flowing from the terminal 145A to the terminal 145B in the device 100A as shown in FIG. 1A.) In this case the hole concentration is observed to increase from a low value to the maximum value of the characteristic 302, but with the hole concentration reduced relative to the characteristic 302 near the insulation layer 125.

FIG. 4 illustrates I-V characteristics for the same example model resistors of FIG. 3, with current shown as function of |V₁-V₂| to account for the bidirectionality of the field-plated well resistor 100A. A characteristic 402 corresponds to the well resistor lacking the field plate, characteristic 404 corresponds to the field-plated well resistor 100A with the field plate 130 connected to the low-side terminal, and characteristic 406 corresponds to the field-plated well resistor 100A with the field plate 130 connected to the high-side terminal. In addition, an “ideal” I-V characteristic 408 having a zero voltage coefficient is included for visual reference. Each of the characteristics 402, 404 and 406 fall below the ideal characteristic 408, indicating the resistance of these characteristics increases with greater voltage across the resistor well 120, thus having a positive voltage coefficient. The characteristic 402 (no field plate) falls about midway between the characteristic 404 (field plate tied to the low-side terminal) and the characteristic 406 (field plate tied to the high-side terminal). Thus, it is apparent that the voltage coefficient of the p-type resistor well 120 may be reduced by inclusion of the field plate 130 connected to the low-side terminal, and may be increased, if desired, by inclusion of the field plate 130 connected to the high-side terminal. Again, it is noted that these effects are reversed for an n-type resistor well, thus providing design flexibility to reduce or increase the voltage coefficient of a resistor well as desired in different circuit configurations. It is further noted that modulation of the voltage coefficient may be done independent of the direction of current flow and majority carrier type by use of the configuration of the field-plated well resistor 100B and additional circuitry to provide a designed bias voltage to the field plate 130.

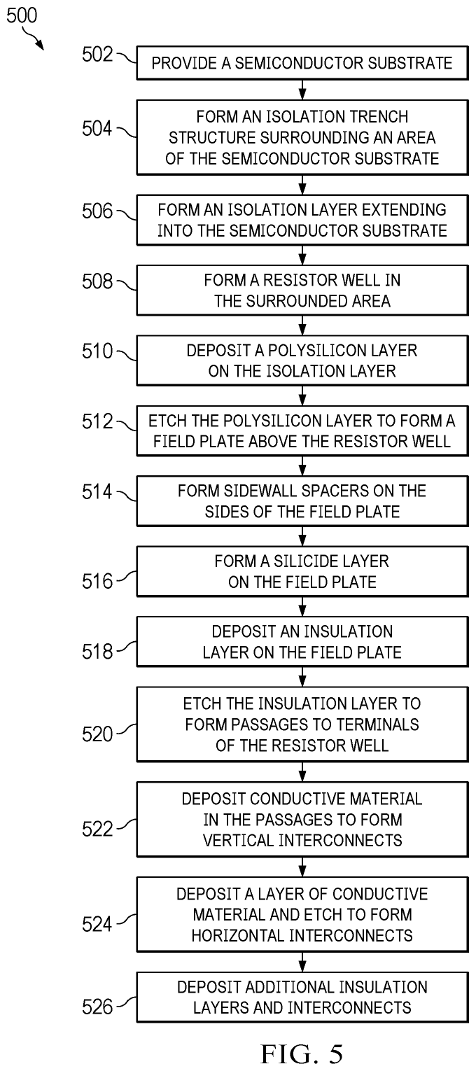

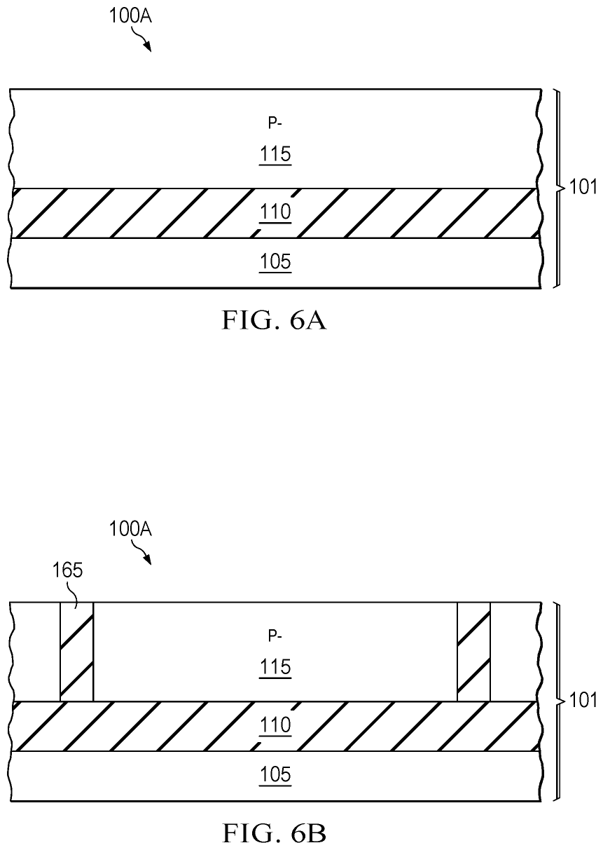

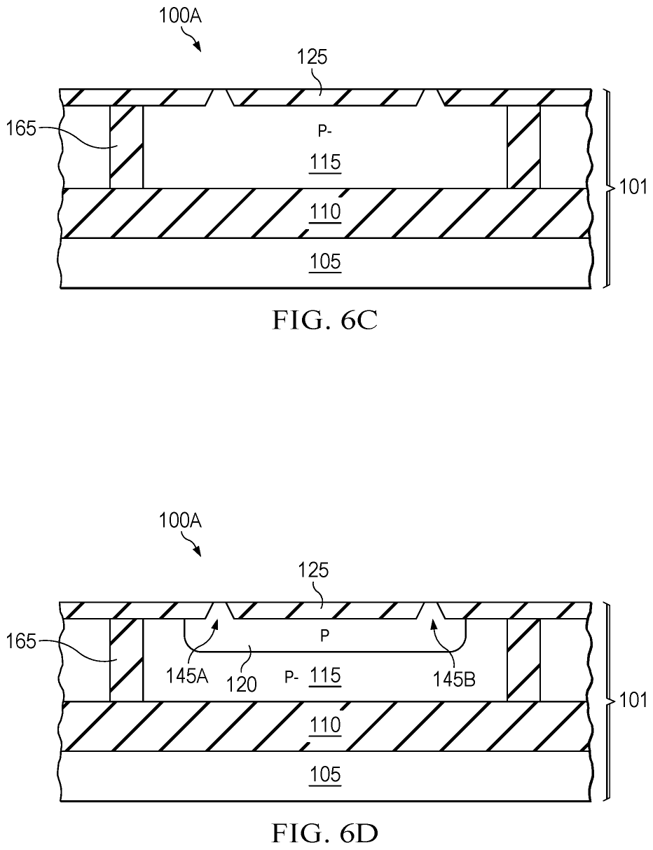

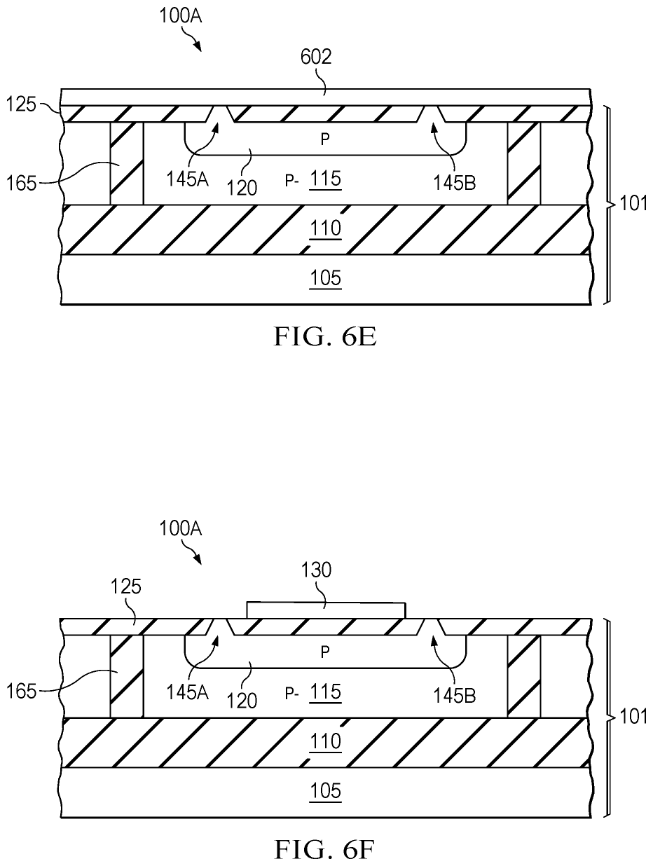

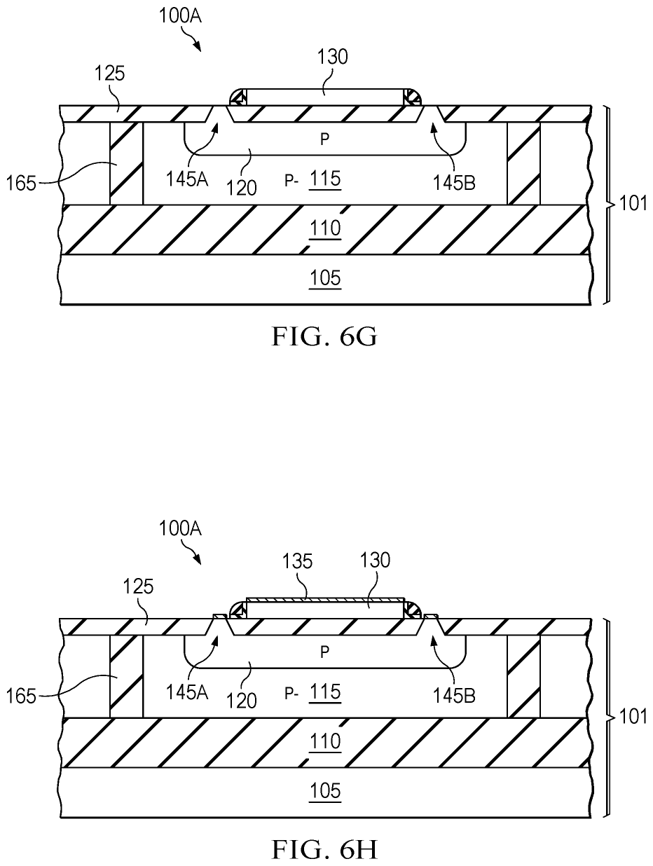

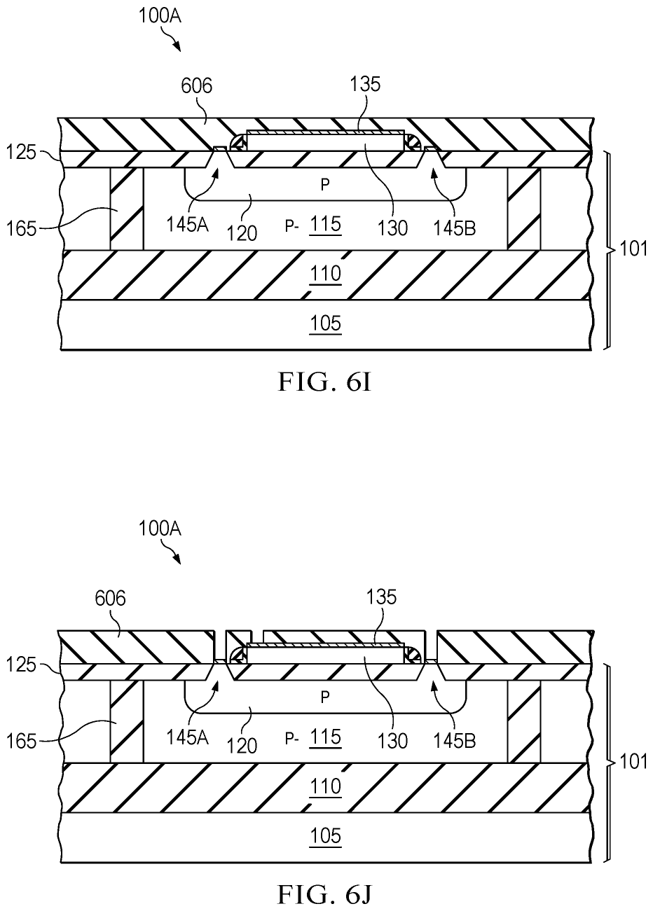

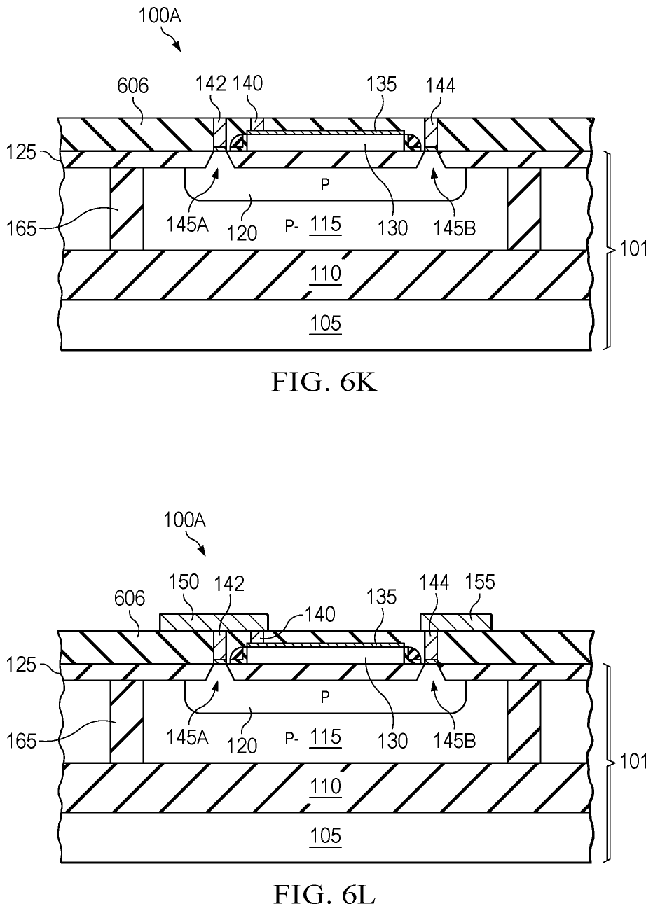

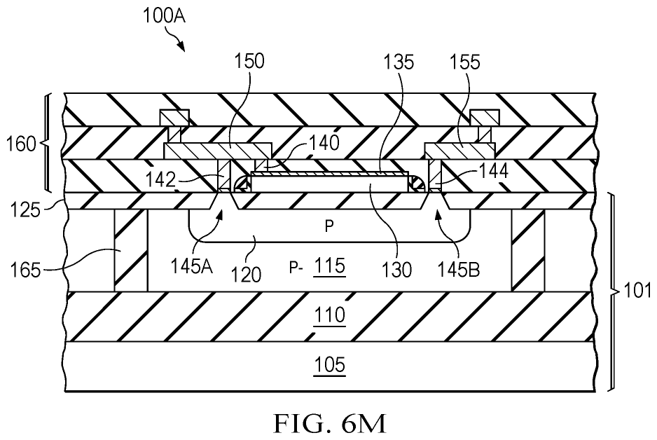

Now turning to FIG. 5, a flow diagram is presented of an example method 500 for fabricating a field-plated well resistor consistent with the field-plated well resistor 100A. FIGS. 6A-6M are cross-section views showing examples of the various fabrication stages of the method of FIG. 5, and are described concurrently with FIG. 5. Though depicted sequentially as a matter of convenience, at least some of the actions shown can be performed in a different order and/or performed in parallel. Additionally, some implementations may perform only some of the actions shown.

In block 502, a semiconductor substrate 101 is provided. FIG. 6A shows the field-plated well resistor 100A at an early stage of manufacturing. The semiconductor substrate 101 may include a handle layer 105, a buried oxide (BOX) layer 110 and an epitaxial layer 115. The handle layer 105 may be bulk silicon or other semiconductor material. The BOX layer 110, which may be omitted in some examples, may be a portion of a silicon-on-insulator (SOI) substrate. While the epitaxial layer 115 in the illustrated example is lightly doped p-type silicon (active silicon), the handle layer 105 and epitaxial layer 115 may be any other combinations of n-type or p-type material.

In block 504, an isolation trench structure 165 (e.g., a deep trench isolator) is etched around an area of the semiconductor substrate 101. The isolation trench structure 165 includes a trench in the semiconductor substrate 101. The trench may be lined or filled with a dielectric material, such as silicon dioxide. In some examples, the dielectric material may be filled with a conductor such as polysilicon. If the substrate is an SOI substrate the isolation trench structure 165 may contact the BOX layer 110 as illustrated in FIG. 6B, thus conductively isolating the resistor well 120 from other devices that share the substrate 101. Similarly for examples that include a buried isolation layer, such as a buried n-type layer, the isolation trench may include n-type polysilicon thereby isolating the resistor well 120 by junction isolation.

In block 506, an insulation layer 125 (e.g., an STI oxide, LOCOS, or nitride layer) is formed on the epitaxial layer 15. Chemical vapor deposition or thermal oxidation processes may be employed to deposit the insulation layer. FIG. 6B shows the insulation layer 125 provided on the epitaxial layer 115. The insulation layer 125 may be patterned to provide access to the epitaxial layer for terminals of the resistor well to be formed.

In block 508, a resistor well 120 is formed in the surrounded area of the semiconductor substrate 101. The resistor well 120 may be formed by doping a well region of the semiconductor substrate 101 with a selected dopant. For example, a p-type dopant (e.g., boron) may be applied to a well region of the semiconductor substrate 102, where the semiconductor substrate 102 is n-type or p-type. FIG. 6C shows the resistor well 120 in the semiconductor substrate 101. The resistor well 120 includes a first terminal 145A and a second terminal 145B passing through the insulation layer 125.

In block 508, an isolation trench structure 165 (e.g., a deep trench isolator) is etched around the resistor well 120. The isolation trench structure 165 includes a trench in the semiconductor substrate 101 around the resistor well 120. The trench may be lined or filled with a dielectric material, such as silicon dioxide. In some examples, the dielectric material may be filled with a conductor such as polysilicon. If the substrate is an SOI substrate the isolation trench structure 165 may contact the BOX layer 110 as illustrated in FIG. 6D, thus conductively isolating the resistor well 120 from other devices that share the substrate 101. Similarly for examples that include a buried isolation layer, such as a buried n-type layer, the isolation trench may include n-type polysilicon thereby isolating the resistor well 120 by junction isolation.

In block 510, a polysilicon layer 602 is deposited on the insulation layer 125. The polysilicon layer 602 may be deposited using chemical vapor deposition (CVD). FIG. 6E shows the polysilicon layer 602 on the insulation layer 125.

In block 512, the polysilicon layer 602 is patterned and etched to form the field plate 130. The field plate 130 is above the resistor well 120, and is isolated from the resistor well 120 by the insulation layer 125.

In block 514, sidewall spacers may be formed on the sides of the field plate 130, such as by first forming a conformal CVD silicon nitride layer over the field plate 130, then forming a CVD silicon oxide layer over the silicon nitride layer, and then performing a blanket etchback of the silicon nitride and silicon oxide layers. FIG. 6G shows resulting unreferenced sidewall spacers 604 on the sides of the field plate 130.

In block 516, a silicide layer 135 is formed on the field plate 130. The silicide layer may be formed by depositing a layer of metal (e.g., titanium, tungsten, or cobalt) on the field plate 130 and annealing to form the silicide layer 135. FIG. 6H shows the silicide layer 135 on the field plate 130.

In block 518, a dielectric layer 606 is deposited on the field plate 130 and insulation layer 125. The dielectric layer 606 may include an oxide, nitride, or other insulation material. The dielectric layer 606 may be deposited by chemical vapor deposition, physical vapor deposition, or other deposition techniques. FIG. 6I shows the dielectric layer 606 on the field plate 130 and the insulation layer 125.

In block 520, the dielectric layer 606 is etched to form passages through the dielectric layer 606 to the terminals 145A and 145B, and the field plate 130. The passages may be etched using a dry etch process. FIG. 6J shows the passages etched through the dielectric layer 606 to the terminals 145A and 145B, and the field plate 130.

In block 522, conductive material is deposited in the passages etched in block 520 to form the vertical interconnects 140, 142, and 144. The conductive material may include tungsten, copper, aluminum, or other material, and may be deposited by physical vapor deposition, chemical vapor deposition, or other deposition techniques. FIG. 6K shows the vertical interconnects 140, 142, and 144.

In block 524, a layer of conductive material (e.g., a first metal layer (M1)) is deposited on the dielectric layer 606. The conductive material may include copper, aluminum, or other conductive material. The layer of conductive material is etched to form the horizontal interconnects 150 and 155 in a first metal layer (M1). The horizontal interconnect 150 connects the field plate 130 and the terminal 145 of the resistor well 120 via the vertical interconnects 140 and 142. The horizontal interconnect 155 connects to the terminal 145B of the resistor well 120 via the vertical interconnect 144. FIG. 6L shows the horizontal interconnects 150 and 155.

In block 526, additional insulation layers may be deposited over the dielectric layer 606 to complete the insulation layers 160, and additional interconnects may be formed within the insulation layers 160. For example, FIG. 6M shows unreferenced vertical interconnects and unreferenced horizontal interconnects of a second metal layer (M2). Such interconnects may serve to connect the field-plated well resistor 100A to other components of the integrated circuit.

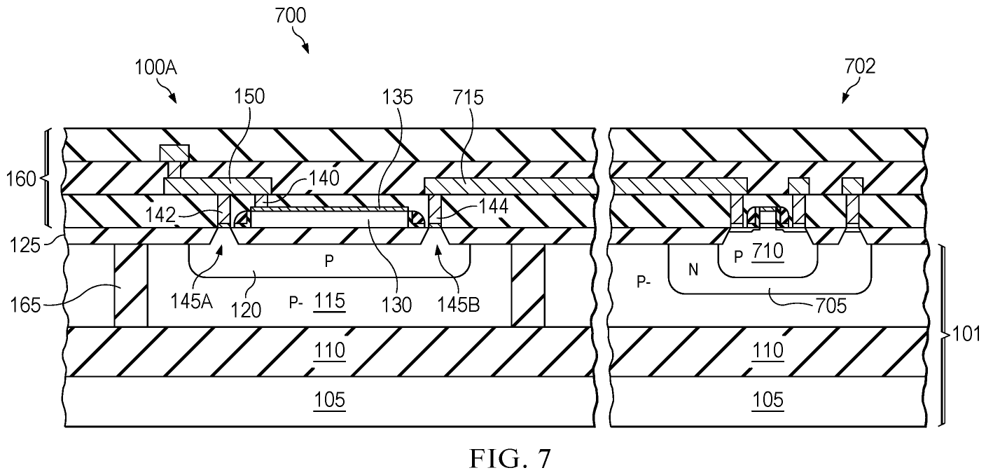

FIG. 7 is a side cross-section view of an integrated circuit 700. The integrated circuit 700 includes the field-plated well resistor 100A and a transistor 702. In practice, the integrated circuit 700 may include any number of transistors and other components in addition to the field-plated well resistor 100A. In some examples, the transistor 702 may include a p-well 710, where the p-well 710 is within an n-well 705 formed in the epitaxial layer 115. A terminal (e.g., drain or source) of the transistor 702 is conductively coupled to a terminal of the field-plated well resistor 100A via a horizontal interconnect 715, while in other examples a gate electrode of the transistor 702 may be conductively coupled to one of the resistor 100A terminals. Another transistor or other device may be coupled to the field-plated well resistor 100A via the horizontal interconnect 150 is some examples.

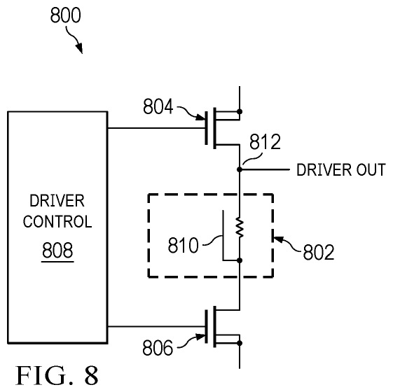

FIG. 8 is a schematic of an example driver circuit 800. The driver circuit 800 includes the field-plated well resistor 802, a high-side transistor 804, a transistor 806, and a driver control circuit 808. The field-plated well resistor 802 includes a field plate 810. The field-plated well resistor 100A may be an example of the field-plated well resistor 802, and the field plate 130 may be an example of the field plate 810. In the illustrated example the field plate 810 is conductively connected to the drain of the transistor 806 (low side of the resistor 802), but in other examples the field plate 810 may be conductively connected to the drain of the transistor 804 (high side of the resistor 802). The transistor 806 may be an n-channel field effect transistor (NFET), and the transistor 804 may be a p-channel field effect transistor (PFET). The transistor 702 may be an example of the transistor 804 or the transistor 806. The field-plated well resistor 802 is coupled between a current terminal (e.g., drain) of the transistor 804 and current terminal (e.g., drain) of the transistor 806. An output signal of the driver circuit 800 is provided at the node 812 connecting the field-plated well resistor 802 to the current terminal of the transistor 804. The driver control circuit 808 is coupled to the control inputs (e.g., gate) of the transistor 804 and the transistor 806. The driver control circuit 808 generates pulses that control switching of the transistor 804 and the transistor 806. The node 812 may be coupled to an ultrasound transducer in some examples.

In some implementations of the driver circuit 800, the transistor 804 may be a drain-extended p-type metal oxide semiconductor (DEPMOS) transistor, and the transistor 806 may be a laterally diffused metal oxide semiconductor (LDMOS) transistor. The transistor 806 may have a significantly lower on resistance than the transistor 804. The field-plated well resistor 100 is coupled between the transistor 806 and the transistor 804 to provide matching of pull-up and pull-down currents when the transistor 806 and the transistor 804 are biased in the linear region. Accordingly, the field-plated well resistor 802 is on the pull-down side of the node 812. Matching of pull-up and pull-down currents reduces distortion. The low voltage coefficient of the field-plated well resistor 802 reduces distortion and power dissipation in the field-plated well resistor 802, which improves the performance of the driver circuit 800.

The same reference numbers or other reference designators are used in the drawings to designate the same or similar (either by function and/or structure) features.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” means that the conduction channel of the FET is present and drain current may flow through the FET. References herein to a FET being “off” means that the conduction channel is not present and drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

What is claimed is:

1. A semiconductor device comprising:
a semiconductor substrate;
a well resistor in the semiconductor substrate;
a field plate above the well resistor; and
an insulator between the well resistor and the field plate.

2. The semiconductor device of claim 1, wherein:
the well resistor includes a first terminal and a second terminal; and
the field plate is conductively connected to the first terminal or the second terminal.

3. The semiconductor device of claim 2, wherein:
the well resistor is a p-type resistor;
the second terminal is configured to receive a current from a current source; and
the field plate is conductively connected to the first terminal.

4. The semiconductor device of claim 2, wherein:
the well resistor is an n-type resistor;
the first terminal is a higher voltage terminal;
the second terminal is a lower voltage terminal; and
the field plate is coupled to the first terminal.

5. The semiconductor device of claim 1, wherein the field plate comprises a polysilicon layer.

6. The semiconductor device of claim 1, wherein the field plate comprises a metal interconnect layer.

7. The semiconductor device of claim 1, further comprising an isolation trench in the semiconductor substrate around the well resistor.

8. The semiconductor device of claim 1, wherein the field plate is connected to a voltage source configured to bias the field plate independent of a voltage on terminals of the well resistor.

9. An integrated circuit comprising:
a resistor well extending into a semiconductor substrate;
a dielectric layer extending into the resistor well; and
a conductive field plate located over the dielectric layer, the conductive field plate configured to modulate a majority carrier distribution within the resistor well while the resistor well conducts a current.

10. The integrated circuit of claim 9, wherein:
the resistor well is p-type;
the conductive field plate is conductively connected to a low-side terminal of the resistor well; and
the conductive field plate is configured to reduce a voltage coefficient of the resistor well.

11. The integrated circuit of claim 9, wherein:
the resistor well is n-type;
the conductive field plate is coupled to a high-side terminal of the resistor well; and
the conductive field plate is configured to reduce a voltage coefficient of the resistor well.

12. The integrated circuit of claim 9, wherein the conductive field plate includes a polysilicon layer.

13. The integrated circuit of claim 9, further comprising an isolation trench that conductively isolates the resistor well from the substrate.

14. The integrated circuit of claim 9, wherein the conductive field plate is configured to increase a voltage coefficient of the resistor well.

15. A method comprising:
forming an insulation layer on a semiconductor substrate;
doping a resistor well extending into the semiconductor substrate below the insulation layer;
depositing a layer of a conductive material spaced apart from the resistor well by the insulation layer; and
etching the conductive material to form a field plate over the resistor well.

16. The method of claim 15, wherein the conductive material includes polysilicon.

17. The method of claim 15, wherein the conductive material is metal and the layer is an interconnect layer.

18. The method of claim 15, further comprising conductively connecting the field plate to the resistor well.

19. The method of claim 15, further comprising forming first and second terminals connected to the resistor well, the first terminal configured to have a higher voltage than the second terminal when conducting a current, and wherein the field plate is conductively connected to the second terminal.

20. The method of claim 15, further comprising forming first and second terminals connected to the resistor well and connecting the first or second terminal to a terminal of a transistor formed over the semiconductor substrate.
